(19) United States
(12) Patent Application Publication
(10) Pub. No.: US 2009/0294776 A1
(43) Pub. Date: Dec. 3, 2009

(54) Highly Oxygen-Sensitive Silicon Layer and Method for Obtaining Same

(75) Inventors: Patrick Soukiassian, Saint Remy Les Chevreuse (FR); Fabrice Semond, Mougins (FR)

Correspondence Address: Nixon Peabody LLP, 200 Page Mill Road, Palo Alto, CA, 94306, US

(73) Assignees: Commissarita A L'Energie Atomique, Paris (FR); Universite Paris Sud (Paris XI), Orsay (FR)

(21) Appl. No.: 11/988,343

(22) PCT Filed: Jul. 4, 2006
(86) PCT No.: PCT/EP2006/063856

§ 371 Date: Jun. 17, 2009

(30) Foreign Application Priority Data
Jul. 5, 2005 (FR) 0552059

(51) Int. Cl. H01L 29/24; H01L 21/31

(52) U.S. Cl. 257/77; 438/770; 257/E29.104; 257/E21.24

(57) ABSTRACT

Silicon layer highly sensitive to oxygen and method for obtaining said layer.

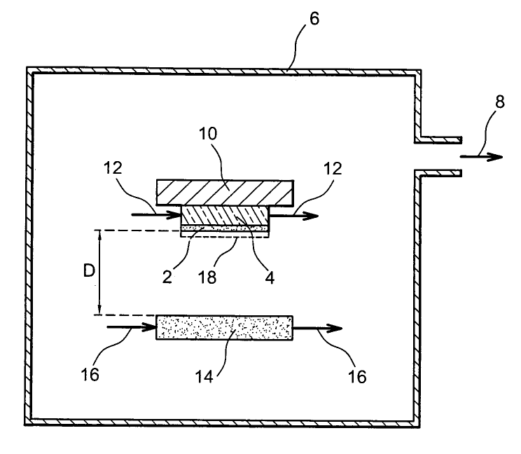

This layer (2), formed on a substrate (4) for example of SiC, has a 3'2 structure. To obtain it, it is possible to substantially uniformly deposit silicon on a surface of the substrate. The invention can be applied for example to microelectronics.

### TECHNICAL FIELD

This invention relates to a silicon layer that is very sensitive to oxygen, as well as a method for obtaining said layer.

It applies in particular to the field of microelectronics.

### PRIOR ART

Silicon carbide (SiC) is a very beneficial IV-IV semiconductor material compound that is suitable in particular for high-power, high-voltage or high-temperature devices and sensors.

Recently, significant progress has been made in the knowledge of surfaces of this material and SiC interfaces with insulators and metals.

Two of the important issues for the success of SiC-based electronic devices (and in particular those based on hexagonal polytypes of this material) involve the obtaining of effective MOS (Metal Oxide Semiconductor) transistors, surface passivation and therefore SiC oxidation, and the Insulator on SiC structure.

We should note that silicon is currently the most widely used semiconductor material, primarily due to the exceptional properties of silicon dioxide (SiO₂).

From this perspective, SiC is especially beneficial since its surface passivation can be achieved by SiO₂ growth, under conditions similar to those of silicon.

However, due to the presence of carbon, the conventional oxidation (direct SiC oxidation) of the SiC surfaces (in particular hexagonal surfaces of this material) generally leads to the formation of Si and C oxides, which have mediocre electrical properties, and to SiO₂/SiC interfaces that are not abrupt, as the transition between SiC and SiO₂ occurs over a plurality of atomic layers.

The electronic mobility in the inversion layers of the MOS on p-SiC structure is much lower (by a factor of 10) than on silicon due to the disorder at the interface.

A method for obtaining passivation, in SiO₂, on SiC is known from document EP-A-0637069 (Cree Research, Inc.). To obtain a SiO₂ layer of 62 nm from a Si layer, according to this document, it is necessary to have thermal oxidation at high temperature (around 1200° C.) and at a very high oxygen pressure (around atmospheric pressure, i.e. around 10⁵ Pa).

But the use of high temperatures and high pressures requires a lot of energy. The production of passivation layers under gentler conditions is therefore a major issue in the electronics industry.

Moreover, the miniaturization of microelectronics devices creates a need for increasingly thin passivation layers, as the interface between a passivation layer and the substrate supporting it becomes increasingly abrupt.

A silicon layer that is sensitive to oxygen at room temperature is also known from document U.S. Pat. No. 6,667,102 A, corresponding to WO 01/39257 A. This layer is formed on hexagonal silicon carbide and has a 4×3 surface structure.

### DISCLOSURE OF THE INVENTION

The present invention is intended to overcome the aforementioned disadvantages.

It relates to a silicon layer that considerably promotes the growth of an oxide on a substrate and results in an abrupt SiO₂/substrate interface, while allowing for oxidation conditions that are gentler than those allowed by the prior art mentioned above.

In addition, the invention makes it possible to obtain passivation layers that are thinner than those obtained by said known prior art.

Specifically, this invention relates to a silicon layer formed, in particular deposited, on a substrate, which layer is characterized in that it has a 3×2 structure, and the substrate is capable of receiving this 3×2 silicon structure or suitable for promoting its formation.

According to a preferred embodiment of the invention, the layer has a 3×2 surface structure (it is also said to be a 3×2 reconstruction), wherein the substrate is capable of receiving this 3×2 silicon surface structure or is suitable for promoting its formation.

The layer is preferably oxidizable at a temperature below or equal to 650° C.

According to a preferred embodiment of the invention, the substrate is silicon carbide β-SiC.

This invention also relates to a silicon oxide layer, which layer results from the oxidation of the silicon layer of the invention.

This invention also relates to a surface covered with this silicon oxide layer.

This invention also relates to a method for obtaining the silicon layer of the invention, in which silicon is substantially uniformly deposited on a surface of the substrate.

This invention also relates to another method, for obtaining a silicon oxide layer on a substrate, which other method is characterized in that it includes the following series of steps:

(a) the formation (in particular the deposition) of the silicon layer of the invention on the substrate, and

(b) the oxidation of this silicon layer.

The oxidation of the silicon layer is preferably carried out at a temperature below or equal to 650° C., and more specifically at a temperature ranging from room temperature to 500° C. This temperature is advantageously the room temperature (around 20° C.).

The SiO/Si or SiO₂/substrate interface, which is obtained after oxidation, is abrupt, with the transition between the substrate and SiO₂ practically occurring over a few atomic layers.

According to a preferred embodiment of this other method, the silicon layer formed (in particular deposited) on the substrate has a 3×2 surface structure (it is also said to be a 3×2 reconstruction), with the substrate being capable of receiving this 3×2 silicon surface structure or suitable for promoting the formation of this structure.

The substrate is preferably made of a material chosen from silicon carbide and silicon.

The silicon carbide can be monocrystalline, polycrystalline, amorphous or porous.

The silicon layer is advantageously formed on a β-SiC surface, preferably on the face (001).

Advantageously, in the present invention, when it is necessary to heat the substrate, it is possible to use the Joule effect, preferably by passing a continuous electric current through the substrate. In addition, the various steps of the method of the invention are preferably performed in a high-vacuum chamber, advantageously the same chamber during the entire method.

Alternatively, the heating of the substrate can be done by electron impact of said substrate.

Preferably, the surface of the substrate is rinsed before forming the silicon layer on said surface. The rinsing is preferably performed with an organic solvent, which solvent advantageously includes ethanol or methanol.

It is preferable for the substrate to be degassed before the formation of the silicon layer.

According to a preferred embodiment of the invention, the substrate is heated, preferably to around 650° C., in particular for silicon carbide, under reduced pressure, advantageously 3×10⁻⁹ Pa, for an adequate time, for example 24 hours, in order to be degassed.

Before forming the silicon layer on the substrate, one or more annealing operations can also be performed on the substrate, until there is no longer any detection of LEED (low-energy electron diffraction) or RHEED (reflection high-energy electron diffraction) contamination. Advantageously, at least one annealing operation, followed by cooling of the substrate, is performed.

Preferably, in particular if the substrate is silicon carbide, each annealing operation is performed as follows:
the substrate is heated at 1000° C. for 3 minutes, then at 1100° C. for 1 minute, then at 1200° C. for 1 minute, then
the substrate is slowly cooled at a rate of 100° C. per minute until it reaches room temperature (around 20° C.).

Such a method makes it possible to deposit silicon substantially uniformly over a surface of the substrate.

The silicon layer of step (a) is preferably formed at room temperature.

The thickness of this layer is preferably less than or equal to 10 nm.

At least one annealing of the silicon layer is preferably performed after the formation of this layer in step (a).

According to a preferred embodiment of the method of the invention, according to the modalities indicated above, a surface of the substrate, kept at room temperature, is prepared for receiving the silicon layer, then the silicon is deposited substantially uniformly on the surface of the substrate, at least one annealing operation is performed on the substrate, on which the silicon has been deposited, at least at 1000° C., with the total annealing time being at least 5 minutes, and the substrate is cooled to room temperature (around 20° C.) at a rate of at least 100° C./minute.

The substrate can also be brought to a temperature above room temperature, for example around 650° C., in order to perform the deposition. The deposition and annealing steps can also be performed simultaneously, with the deposition being performed in this case at high temperature.

Preferably, in particular if the substrate is made of a monocrystalline silicon carbide, the silicon layer is formed on this substrate at room temperature, then the assembly constituted by the substrate and this layer is subjected to at least one annealing operation at least at 650° C., with the total annealing time being at least 7 minutes, and the annealing operation(s) being followed by cooling at a rate of at least 50° C./minute.

Preferably, in particular if the substrate is made of a monocrystalline silicon carbide, the preparation of the surface of the substrate to receive the monocrystalline silicon and/or to promote the formation of the latter includes an auxiliary heating of the substrate at least at 1000° C., a substantially uniform auxiliary deposition of monocrystalline silicon on the surface of the substrate thus heated and at least one auxiliary annealing of the substrate after this auxiliary deposition, at least at 650° C., with the total auxiliary annealing time being at least 7 minutes.

Before the auxiliary heating, the preparation of the surface of the substrate preferably includes a degassing of the substrate under ultra-high vacuum, then at least one annealing of said substrate, followed by cooling of the substrate.

In the present invention, the silicon layer is preferably formed by vacuum evaporation.

It should be noted that this layer can be formed in other ways, for example by chemisorption/interaction of silane or by evaporation by electron impact of a silicon sample.

According to a preferred embodiment of the invention, the silicon is deposited on the substrate from a silicon sample of which the surface is larger than that of the substrate.

Preferably, the surface of the silicon sample and the surface of the substrate are separated by a distance on the order of 2 to 3 cm.

According to the invention, the oxidation of the silicon layer is performed after the deposition of the silicon layer, advantageously in the same chamber.

Preferably, the oxidation of the silicon layer is performed with an oxygen exposure in the range of 8000 langmuirs (around 0.8 Pa·s) to 15,000 langmuirs (around 1.5 Pa·s), with this exposure preferably being equal to 10,000 langmuirs (around 1 Pa·s).

With the method for obtaining an oxide layer according to the invention, it is possible to increase the thickness of the oxide to 10 nm with an interface that remains abrupt. To obtain an identical result, it is advantageously possible to increase the amount of oxide by greater exposures to oxygen and by slightly higher temperatures, close to 650° C.

In this invention, annealing operations can be performed after oxidation of the 3×2 silicon layer structure.

The present invention is very useful for producing MOS devices, and in particular MOSFET devices (MOS field-effect transistors).

It is also useful for the passivation of any component, not only on silicon carbide, but also on silicon or other substrates, on which such a 3×2 silicon structure can be deposited.

A silicon dioxide layer (SiO₂) obtained by the method, which constitutes the main subject matter of the invention, is subject to less damage under the impact of incident ionizing radiation than the SiO₂ layers of the prior art, since it can be performed at a lower temperature than these layers, it is thin (it is capable of having a thickness as low as 1 nm and in any case less than or equal to 8 nm) and it has an abrupt interface with the underlying substrate.

### BRIEF DESCRIPTION OF THE DRAWINGS

This invention can be better understood on reading the descriptions of example embodiments provided below, purely for indicative and non-limiting purposes, in reference to the single appended FIGURE that diagrammatically shows the production of a silicon layer according to the invention.

### DETAILED DESCRIPTION OF SPECIFIC EMBODIMENTS

It is first indicated that a silicon layer with a 3×2 structure can be obtained according to the modalities described in document FR 2 823 770 A, corresponding to US 2004/0104406 A.

An example of a preparation of a silicon layer according to the invention will now be provided.

In this example, a cubic monocrystalline silicon carbide sample is used, which is commercially available from the NovaSiC and Hoya companies, as well as from the LETI (a laboratory of the Atomic Energy Commission).

The face of this sample used is face (100).

This sample can be constituted by a thin film, with a thickness greater than or equal to 1 μm, epitaxially grown on a silicon wafer, or it can be a bulk sample, with a thickness of around 300 μm. In addition, this sample has, for example, a length of 13 mm and a width of 5 mm.

We begin by preparing a 3×2 reconstructed clean β-SiC surface (100) from the sample.

The sample is first rinsed with ethanol or methanol.

Then, the sample is placed in a high-vacuum chamber where a pressure on the order of 3×10⁻⁹ Pa is established and where said sample is heated by direct Joule effect by the passage of an electric current through the sample.

The temperature of the latter is measured using an infrared pyrometer.

First, the sample is degassed by leaving it for 24 hours at 650° C. under ultra-high vacuum.

The sample is then subjected to a series of annealing operations until no contaminant is detected, for example by photoemission, and until the surface of the sample is clean, which is verified by LEED or RHEED:
the sample is heated at 1000° C. for 3 minutes, then at 1100° C. for 1 minute, then at 1200° C. for 1 minute, then
the sample is then slowly cooled at a rate of 100° C. per minute until it reaches room temperature (around 20° C.).

Then, for 10 minutes, using vacuum evaporation performed with a clean silicon sample (having, for example, a length of 20 mm and a width of 10 mm), which is heated to 1150° C., silicon is deposited uniformly on the surface of the silicon carbide sample kept at room temperature.

During this deposition, the silicon carbide sample and the silicon sample face one another at a distance D of 2 cm from one another.

The largest surface of the silicon sample allows for the homogeneity, i.e. the uniformity, of the silicon deposit on the silicon carbide sample.

Finally, for the SiC sample thus coated with silicon, the series of annealing operations described above is performed again: this sample is heated at 1000° C. for 3 minutes, then at 1100° C. for 1 minute, then at 1200° C. for 1 minute.

The sample thus coated with Si is then subjected to a new series of annealing operations; 1 minute at 750° C. then 1 minute at 700° C. then 5 minutes at 650° C.

The sample is then slowly cooled to room temperature, at a rate of 50° C. per minute.

The β-SiC surface (100) thus obtained has a 3×2 structure (square unit cell).

The 3×2 reconstructed areas have dimensions on the order of 550 nm×450 nm, can have a low step density and have a few Si islands in 3×2 formation. The 3×2 reconstructed islands are then selected for the next step.

Silicon can then be added and allows for epitaxial growth of a 3×2 reconstructed silicon layer.

It is thus possible to obtain a silicon layer of which the thickness corresponds to a plurality of atomic layers (from 1 nm to 10 nm).

The organization of this Si layer in a 3×2 structure is thus achieved by a series of annealing operations at 750° C., then at 700° C., then at 650° C., as described above.

The single appended FIGURE very diagrammatically shows the production of the silicon layer 2, having a 3×2 structure, on the clean surface of the 3×2 reconstructed substrate 4 of β-SiC (100).

It is also possible to see the chamber 6 in which the preparation of the substrate 4 and the formation of the layer 2 take place.

The pumping means making it possible to obtain the ultra-high vacuum are symbolized by arrow 8.

The substrate 4 is mounted on a suitable support 10, and the means for heating the substrate by Joule effect are symbolized by arrows 12.

It is also possible to see means for heating the silicon sample 14 by the Joule effect, which means are symbolized by arrows 16.

The oxidation of the silicon layer having a 3×2 structure will now be described.

This oxidation occurs as follows: the sample covered with a 3×2 Si layer is exposed to oxygen, while being kept at a temperature ranging from 25° C. to 650° C.; the oxygen exposure is equal to 10⁴ langmuirs (around 1 Pa·s).

Under these conditions, a silicon oxide layer, as represented with a dotted line in the FIGURE (reference 18), is obtained, which silicon oxide layer has an average thickness of 1 nm.

Greater thicknesses, for example 10 nm, can be obtained by increasing the amount of oxygen provided as well as the temperature.

The last process can be performed several times, with the interface between the SiO₂ and the substrate remaining abrupt.

Samples of variable thicknesses, depending on requirements, can therefore be obtained by varying the oxygen exposure.

The oxidation of the silicon layer 2 is preferably performed in chamber 6. In this case, this chamber is equipped with means necessary for this oxidation, in particular an oxygen inlet (not shown).

1. Silicon layer formed on a substrate, which layer (2) is characterized in that it has a 3×2 structure, wherein said substrate (4) is capable of receiving said 3×2 silicon structure or is suitable for promoting its formation.

2. Layer according to claim 1, characterized in that it has a 3×2 surface structure, wherein the substrate (4) is capable of receiving said 3×2 silicon surface structure or is suitable for promoting its formation.

3. Layer according to claim 1, said layer being oxidizable at a temperature below or equal to 650° C.

4. Layer according to claim 1, wherein the substrate (4) is silicon carbide β-SiC.

5. Silicon oxide layer (18) formed on the layer (2) according to claim 1.

6. Surface covered with the silicon oxide layer according to claim 5.

7. Method for obtaining the layer according to claim 1, wherein silicon is substantially uniformly deposited on a surface of the substrate (4).

8. Method for obtaining a silicon oxide layer on a substrate (4), characterized in that it includes the following series of steps:
(a) the formation of a silicon layer (2) according to claim 1 on the substrate, and
(b) the oxidation of this silicon layer.

9. Method according to claim 8, wherein the oxidation of the silicon layer is carried out at a temperature below or equal to 650° C.

10. Method according to claim 9, wherein the oxidation of the silicon layer is carried out at room temperature.

11. Method according to claim 8, wherein the substrate (4) is made of silicon carbide or silicon.

12. Method according to claim 8, wherein step (a) is preceded by a step of rinsing the surface of the substrate, on which the silicon layer (2) is then formed.

13. Method according to claim 12, wherein the rinsing is performed with an organic solvent.

14. Method according to claim 13, wherein the organic solvent includes ethanol or methanol.

15. Method according to claim 8, wherein step (a) is preceded by a step of degassing the substrate.

16. Method according to claim 15, wherein the degassing is performed by heating the substrate under reduced pressure.

17. Method according to either one of claims 15 and 16, wherein the degassing is performed at around 650° C., under a pressure of 3×10⁻⁹ Pa.

18. Method according to claim 8, wherein at least one annealing of the substrate is performed before the formation of the silicon layer at step (a).

19. Method according to claim 18, wherein each annealing operation is performed as follows:
the substrate is heated at 1000° C. for 3 minutes, then at 1100° C. for 1 minute, then at 1200° C. for 1 minute, then the substrate is cooled at a rate of 100° C. per minute until it reaches room temperature.

20. Method according to claim 8, wherein the silicon layer is formed by vacuum evaporation, by chemisorption/interaction of silane or by evaporation by electron impact of a silicon sample.

21. Method according to claim 8, wherein the silicon layer (2) of step (a) is formed at room temperature.

22. Method according to claim 8, wherein the thickness of the silicon layer formed in step (a) is less than or equal to 10 nm.

23. Method according to claim 8, wherein at least one annealing of the silicon layer is performed after the formation of said layer in step (a).

24. Method according to claim 8, wherein the silicon layer (2) is formed on the substrate at room temperature, then the assembly constituted by said substrate and said layer is subjected to at least one annealing operation at least at 650° C., with the total annealing time being at least equal to 7 minutes, and the annealing operation(s) being followed by cooling at a rate of at least 50° C./minute.

25. Method according to claim 8, wherein the oxidation of the silicon layer (2) is performed with an oxygen exposure ranging from around 0.8 Pa·s to around 1.5 Pa·s.
